(19) United States
(12) Patent Application Publication
(10) Pub. No.: US 2006/0208354 A1
(43) Pub. Date: Sep. 21, 2006

(54) Thermal interface structure and process for making the same

(75) Inventors: Chang-Hong Liu, Beijing (CN); Shou-Shan Fan, Beijing (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignees: Tsinghua University, Beijing City (CN); HON HAI Precision Industry CO., LTD., Tu-Cheng City (TW)

(21) Appl. No.: 11/371,995

(22) Filed: Mar. 8, 2006

(30) Foreign Application Priority Data
Mar. 19, 2005 (CN) 200510033746.3

(51) Int. Cl. H01L 23/34; H01L 21/00

(52) U.S. Cl. 257/707; 257/E23.107; 257/706; 438/122

(57) ABSTRACT

A thermal interface structure (10, 20) is provided for a highly conductive thermal interface between an electronic component and a cooling device for dissipating heat generated by the electronic component. The thermal interface structure includes a matrix (12, 22) and a plurality of carbon nanotubes (14, 24) incorporated in the matrix. The matrix is generally made from a phase change material. A method for making a thermal interface structure is also provided.

### BACKGROUND

1. Technical Field

The invention relates generally to thermal interface structures, and more particularly to a thermal interface structure that employs carbon nanotubes to reduce thermal resistance between an electronic component, such as a central processing unit (CPU), and a cooling device, such as a heat sink. The invention also relates to a process for forming a thermal interface structure.

2. Discussion of Related Art

With the continually decreasing size of electronic and micromechanical devices, increasing emphasis is laid on improving cooling, thus preventing from structural damage. Cooling devices, such as fans, heat sinks, water-cooling devices and heat pipes, are widely used. The cooling devices are directly assembled onto an electronic component, and a dissipation surface of each of the cooling devices touches a dissipation surface of the electronic component. Heat generated by the electronic component is transmitted to the cooling devices via the dissipation surfaces and dissipated. In general, the dissipation surfaces are unlikely to be smooth enough to allow intimate contact, thus the contact area of the dissipation surfaces is only about 10% of total of the dissipation surface area. Air that has high heat resistance fills in intervening space between the dissipation surfaces. Thus, the heat dissipation efficiency between the electronic component and the cooling device is greatly impacted by poor contact between dissipation surfaces.

To solve the above problem, a thermal interface structure is provided between the electronic device and the cooling device to increase contact area of the dissipation surfaces, thus enhancing the heat conducting efficiency. Conventional thermal interface structures are made from a composite material formed by diffusing particles with a high heat conduction coefficient in a base material. The particles can be made of graphite, boron nitride, silicon oxide, alumina, silver, or other suitable materials. The heat conduction coefficient of this kind heat interface structure depends on the base material chosen. Generally, the base material is selected the lipin or phase change materials, heat conduction coefficient thereof being about 1 W/niK (watts/milliKelvin) at room temperature. However, the flexibility of the base material decreases as the quantity of particles is increased, this effects the contact between the surfaces and thus effects the heat conduction.

Another kind of thermal interface structure has recently been developed. The thermal interface structure is obtained by fixing carbon nanotubes in a polymer by injection molding. The carbon nanotubes are distributed directionally, and each carbon nonotube provides a heat conduction path. A heat conduction coefficient of this kind of thermal interface structure can be 6600 W/niK at room temperature, as disclosed in an article entitled “Unusually High Thermal Conductivity of Carbon Nanotubes” by Savas Berber (page 4613, Vol. 84, Physical Review Letters 2000). However, this kind of the thermal interface structure can only be manufactured at high cost, because only one thermal interface structure can be formed by an injection molding process. Furthermore, the unwanted polymer must be removed by an etching method or a mulling method so that ends of the carbon nanotubes can be exposed to enhance the heat conduction coefficient.

Therefore, a heretofore unaddressed need exists in the industry for a method which can address the aforementioned deficiencies and inadequacies with respect to thermal interface structure and method of manufacturing of the same.

### SUMMARY

A thermal interface structure for heat dissipation includes a matrix and a plurality of carbon nanotubes incorporated in the matrix. The matrix is comprised of a phase change material.

A method for manufacturing a thermal interface structure generally includes the steps of:
(a) providing a plurality of carbon nanotubes, and a phase change material;
(b) melting the phase change material;
(c) mixing the nanotubes into the phase change material thereby forming an admixture; and
(d) cooling the admixture at room temperature thereby obtaining the thermal interface structure.

Other advantages and novel features of the present thermal interface structure and its method of manufacture will become more apparent from the following detailed description of preferred embodiments when taken in conjunction with the accompanying drawings.

### BRIEF DESCRIPTION OF THE DRAWINGS

Many aspects of the present thermal interface structure and method for making such can be better understood with reference to the following drawings. The components in the drawings are not necessarily drawn to scale, the emphasis instead being placed upon clearly illustrating the principles of the present thermal interface structure and related manufacturing method. Moreover, in the drawings, like reference numerals designate corresponding parts throughout the several views.

FIG. 1 is a cross-section view of a thermal interface structure in accordance with an exemplary embodiment of the present invention;

FIG. 2 is a cross-section view of a thermal interface structure in accordance with another embodiment of the present invention; and

FIG. 3 is a flow chart showing successive stages in a process for making a plurality of the thermal interface structures of FIG. 1.

Corresponding reference characters indicate corresponding parts throughout the several views. The exemplifications set out herein illustrate at least one preferred embodiment of the present thermal interface structure and method for making such, in one form, and such exemplifications are not to be construed as limiting the scope of the invention in any manner.

### DETAILED DESCRIPTION

Reference will now be made to the drawings to describe embodiments of the present thermal interface structure and its method of manufacture in detail.

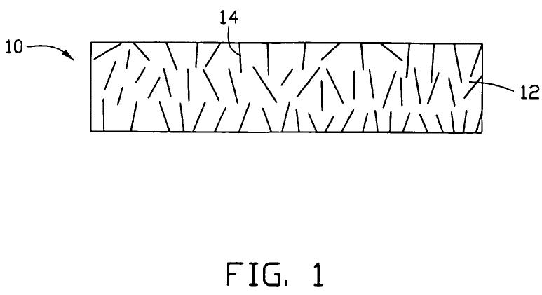

Referring to FIG. 1, a thermal interface structure 10 in accordance with a preferred embodiment of the present thermal interface structure is shown. The thermal interface structure 10 is generally adapted for being disposed between electronic components (not shown) such as central processing units (CPUs), and cooling devices (not shown) such as heat sinks, to dissipate heat generated by the electronic components. The thermal interface structure 10 comprises a matrix 12 and a plurality of carbon nanotubes 14 incorporated in the matrix 12.

The matrix 12 is made from a phase change material with a solid to liquid phase-change temperature in the range of 50° C.˜60° C. (e.g. paraffin material). The nanotubes 14 are dispersed in the matrix 12 randomly. Preferably, the percent by mass of the nanotubes 14 is in the range of about 0.1%˜5%.

In use, the thermal interface structure 10 is disposed between the electronic component and the cooling device, with two opposite surfaces thereof touching a top dissipation surface of the electronic component and a bottom dissipation surface of the cooling device. Heat generated by the electronic component is transmitted to the thermal interface structure 10. When the temperature is in the range of about 50° C.˜60° C., the thermal interface structure 10 changes phase from a solid phase to a fluid phase. Thus, the thermal interface structure 10 fills in the spaces between the dissipation surfaces, and ends of the nanotubes 14 touch the dissipation surfaces to provide heat conduction paths. Therefore, a high heat conduction coefficient of the thermal interface structure 10 is obtained. When the electronic component does not generate heat, the thermal interface structure 10 changes phase from a fluid phase to a solid phase.

Alternatively, an additive material such as dimethylsulfoxide can be used in the thermal interface structure 10 to improve the flexibility and stability of the matrix 12. The additive material is incorporated in the phase change material to form the matrix 12, and can also adjust the phase-change temperature of the phase change material to suit different requirements.

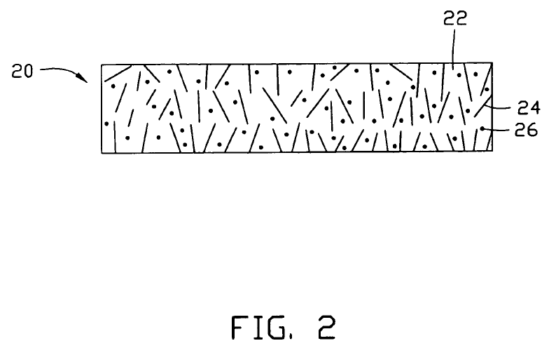

Referring to FIG. 2, a thermal interface structure 20 in accordance with another embodiment of the present thermal interface structure is shown. The thermal interface structure 20 comprises a matrix 22 and a plurality of carbon nanotubes 24 incorporated in the matrix 22. The matrix 22 is made from a phase change material, preferably with an additive material incorporated therein. Furthermore, a number of heat conducting particles 26 distinct from the carbon nanotubes 24 are dispersed in the thermal interface structure 20 to improve the heat conduction coefficient of the thermal interface structure 20. The particles 26 are made from either a nano metal material, a nano ceramic material or an admixture thereof. The metal material is selected from a group consisting of aluminum (Al), silver (Ag) and copper (Cu). The ceramic material is selected from a group consisting of alumina, aluminum nitride, and boron nitride. Preferably, the percentage by mass of the particles 26 is in the range of about 0.1%˜5%.

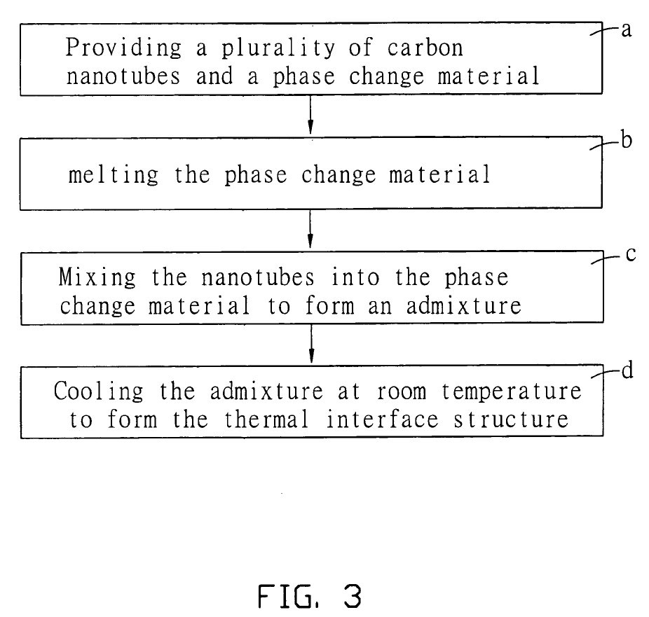

Referring to FIG. 3, the process for making the above-mentioned thermal interface structures 10, 20 is shown. The process generally includes the steps of:
(a) providing a plurality of carbon nanotubes 14, 24, and a phase change material;
(b) melting the phase change material;
(c) mixing the nanotubes 14, 24 in the phase change material and dispersing the nanotubes 14, 24 thereby forming an admixture; and
(d) cooling the admixture at room temperature thereby forming the thermal interface structure.

In step (a), the nanotubes 14, 24 are formed by, for example, an arc-discharge method or a chemical vapor deposition method. Preferably, the percent by mass of the nanotubes 14, 24 is in the range of about 0.1%˜5%.

In step (b), the phase change material is heated at a temperature of about 60° C. In step (c), the nanotubes are dispersed in the phase change material using ultrasound over a time period of about 20 to 40 minutes.

Alternatively, in another method for making the thermal interface structures 10, 20, before the step (a), the nanotubes 14, 24 are cleansed in a boiled acid solution which has oxidation ability for a time period of about 5 minutes to about 30 minutes, in order to increase the quality thereof and reactivity with other material. Alternatively, in steps (a) through (d), an additive material (e.g. dimethylsulfoxide) could be provided and mixed in the melt phase change material to obtain the thermal interface structure 10, 20.

Alternatively, in the method for making the thermal interface structures 10, 20, a plurality of heat conducting particles 26 can be used to improve the heat conduction coefficient of the thermal interface structure 10, 20. If the particles 26 are used, in step (a), the particles 26 would also be provided. In step (c), the particles 26 are dispersed in the phase change material at a temperature of about 60° C. Preferably, the percent by mass of the particles 26 is in the range of about 0.1%˜5%.

Alternatively, after step (d), a step (e) of slicing the thermal interface structure into a plurality of thermal interface pieces could be performed. Each of the thermal interface pieces has a thickness in the range of about 1 μm to about 30 μm. The ends of the nanotubes 14, 24 are thus exposed from surfaces of the matrix 12, 22.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

We claim:

1. A thermal interface structure for heat dissipation, comprising:
a matrix comprised of a phase change material; and
a plurality of carbon nanotubes incorporated in the matrix.

2. The thermal interface structure as claimed in claim 1, wherein the percent by mass of the nanotubes is in the range of about 0.1%˜5%.

3. The thermal interface structure as claimed in claim 1, further comprising an additive material incorporated in the phase change material.

4. The thermal interface structure as claimed in claim 3, wherein the additive material is comprised of dimethylsulfoxide.

5. The thermal interface structure as claimed in claim 1, wherein a solid to liquid phase-change temperature of the phase change material is in the range of about 50° C.˜60° C.

6. The thermal interface structure as claimed in claim 5, wherein the phase change material is comprised of paraffin material.

7. The thermal interface structure as claimed in claim 1, further comprising a plurality of heat conduction particles dispersed in the phase change material, and the percent by mass of the particles being in the range of about 0.1%˜5%.

8. The thermal interface structure as claimed in claim 7, wherein the particles are nano-sized and comprised of one of a metallic material, a ceramic material and an admixture thereof.

9. The thermal interface structure as claimed in claim 8, wherein the metal material is selected from a group consisting of aluminum, silver and copper.

10. The thermal interface structure as claimed in claim 8, wherein the ceramic material is selected from a group consisting of alumina, aluminum nitride, and boron nitride.

11. A method for making a thermal interface structure, comprising the steps of
(a) providing a plurality of carbon nanotubes, and a phase change material;
(b) melting the phase change material;
(c) mixing the nanotubes into the phase change material thereby forming an admixture; and
(d) cooling the admixture at room temperature thereby obtaining the thermal interface structure.

12. The method for making the thermal interface structure as claimed in claim 11, wherein the nanotubes are formed by one of an arc-discharge method and a chemical vapor deposition method.

13. The method for making the thermal interface structure as claimed in claim 12, wherein the nanotubes are cleansed in a boiled acid solution which has oxiding properties for a time period of about 5 to 30 minutes.

14. The method for making the thermal interface structure as claimed in claim 11, wherein in the step (a), a solid to liquid phase-change temperature of the phase change material is in the range of about 50° C.˜60° C.

15. The method for making the thermal interface structure as claimed in claim 14, wherein the phase change material is comprised of paraffin material.

16. The method for making the thermal interface structure as claimed in claim 11, wherein an additive material is mixed into the phase change material.

17. The method for making the thermal interface structure as claimed in claim 16, wherein the additive material is comprised of dimethylsulfoxide.

18. The method for making the thermal interface structure as claimed in claim 11, wherein in the step (c), the nanotubes are dispersed in the phase change material using ultrasound for a time period of about 20 to about 40 minutes.

19. The method for making the thermal interface structure as claimed in claim 11, wherein a plurality of heat conduction particles are mixed in with the phase change material, and the percent by mass of the particles is in the range of about 0.1%˜5%.

20. The method for making the thermal interface structure as claimed in claim 11, further comprising step (e): slicing the thermal interface structure into a plurality of thermal interface pieces each having a thickness in the range from about 1 μm to about 30 μm.
